(19) United States
(12) Patent Application Publication
(10) Pub. No.: US 2024/0162158 A1
(43) Pub. Date: May 16, 2024

(54) PACKAGE ARCHITECTURE WITH MICROFLUIDIC CHANNELS IN GLASS SUBSTRATES

(71) Applicant: Intel Corporation, Santa Clara, CA (US)

(72) Inventors: Brandon C. Marin, Gilbert, AZ (US); Gang Duan, Chandler, AZ (US); Jeremy Ecton, Gilbert, AZ (US); Sashi Shekhar Kandanur, Phoenix, AZ (US); Ravindranath Vithal Mahajan, Chandler, AZ (US); Suddhasattwa Nad, Chandler, AZ (US); Srinivas V. Pietambaram, Chandler, AZ (US); Hiroki Tanaka, Gilbert, AZ (US)

(73) Assignee: Intel Corporation, Santa Clara, CA (US)

(21) Appl. No.: 18/055,605

(22) Filed: Nov. 15, 2022

(51) Int. Cl. H01L 23/538; B81B 1/00; H01L 23/31; H01L 23/467; H01L 23/498

(52) U.S. Cl. CPC H01L 23/5386; B81B 1/002; H01L 23/3121; H01L 23/467; H01L 23/49866; H01L 23/5381; H01L 23/5384; B81B 2201/0214; H01L 24/16; H01L 2224/16227

(57) ABSTRACT

Embodiments of a microelectronic assembly includes: an interposer comprising a first portion in contact along an interface with a second portion; a first integrated circuit (IC) die embedded in a dielectric material in the first portion of the interposer; and a second IC die coupled to the first portion of the interposer opposite to the second portion, wherein: the second portion comprises a glass substrate with a channel within the glass substrate, a portion of the channel has an opening at the interface, a conductive pad in the first portion is exposed in the opening, and the conductive pad is coupled to a circuit in at least one of the first IC die or the second IC die.

### TECHNICAL FIELD

The present disclosure relates to techniques, methods, and apparatus directed to a package architecture with microfluidic channels in glass substrates.

### BACKGROUND

Electronic circuits when commonly fabricated on a wafer of semiconductor material, such as silicon, are called integrated circuits (ICs). The wafer with such ICs is typically cut into numerous individual dies. The dies may be packaged into an IC package containing one or more dies along with other electronic components such as resistors, capacitors, and inductors. The IC package may be integrated onto an electronic system, such as a consumer electronic system, or servers, such as mainframes.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1A is a schematic cross-sectional view of an example microelectronic assembly according to some embodiments of the present disclosure.

FIG. 1B is a schematic exploded perspective view of the portion of microelectronic assembly of FIG. 1A.

FIG. 1C is a schematic cross-sectional view of another portion of microelectronic assembly of FIG. 1A.

FIG. 1D is a schematic plan view of a portion of microelectronic assembly of FIG. 1A.

FIG. 2A is a schematic cross-sectional view of an example microelectronic assembly according to another embodiment of the present disclosure.

FIG. 2B is a schematic plan view of a portion of microelectronic assembly of FIG. 2A.

FIG. 3A is a schematic cross-sectional view of an example microelectronic assembly according to another embodiment of the present disclosure.

FIG. 3B is a schematic plan view of a portion of microelectronic assembly of FIG. 2A.

FIG. 4A is a simplified cross-sectional view of a detail in the microelectronic assembly according to various embodiments of the present disclosure.

FIGS. 4B-4C are simplified cross-sectional views of the microelectronic assembly at various stages of operation.

FIG. 5 is a simplified cross-sectional view of a detail in the microelectronic assembly according to various embodiments of the present disclosure.

FIG. 6 is a simplified block diagram of an example operation using the microelectronic assembly according to various embodiments of the present disclosure.

FIGS. 7A-7E are schematic cross-sectional views of a portion of the microelectronic assembly at various stages of manufacture according to some embodiments of the present disclosure.

FIG. 8 is a cross-sectional view of a device package that includes one or more microelectronic assemblies in accordance with any of the embodiments disclosed herein.

FIG. 9 is a cross-sectional side view of a device assembly that includes one or more microelectronic assemblies in accordance with any of the embodiments disclosed herein.

FIG. 10 is a block diagram of an example computing device that includes one or more microelectronic assemblies in accordance with any of the embodiments disclosed herein.

### DETAILED DESCRIPTION

### Overview

For purposes of illustrating IC packages described herein, it is important to understand phenomena that may come into play during assembly and packaging of ICs. The following foundational information may be viewed as a basis from which the present disclosure may be properly explained. Such information is offered for purposes of explanation only and, accordingly, should not be construed in any way to limit the broad scope of the present disclosure and its potential applications.

The demand for miniaturization of form factor and increased levels of integration for high performance are driving sophisticated packaging approaches in the semiconductor industry. Advances in semiconductor processing and logic design have permitted an increase in the amount of logic circuits that may be included in processors and other IC devices. As a result, many processors now have multiple cores that are monolithically integrated on a single die. Generally, these types of monolithic ICs are also described as planar since they take the form of a flat surface and are typically built on a single silicon wafer made from a monocrystalline silicon boule. The typical manufacturing process for such monolithic ICs is called a planar process, allowing photolithography, etching, heat diffusion, oxidation, and other such processes to occur on the surface of the wafer, such that active circuit elements (e.g., transistors and diodes) are formed on the planar surface of the silicon wafer.

Current technologies permit hundreds and thousands of such active circuit elements to be formed on a single die so that numerous logic circuits may be enabled thereon. In such monolithic dies, the manufacturing process must be optimized for all the circuits equally, resulting in trade-offs between different circuits. In addition, because of the limitation of having to place circuits on a planar surface, some circuits are farther apart from some others, resulting in decreased performance such as longer delays. The manufacturing yield may also be severely impacted because the entire die may have to be discarded if even one circuit is malfunctional.

One solution to overcome such negative impacts of monolithic dies is to disaggregate the circuits into smaller dies (e.g., chiplets, tiles) electrically coupled by interconnect bridges. The smaller dies are part of an assembly of interconnected dies that together form a complete IC in terms of application and/or functionality, such as a memory chip, microprocessor, microcontroller, commodity IC (e.g., chip used for repetitive processing routines, simple tasks, application specific IC, etc.), and system-on-a-chip (SOC). In other words, the individual dies are connected to create the functionalities of a monolithic IC. By using separate dies, each individual die can be designed and manufactured optimally for a particular functionality. For example, a processor core that contains logic circuits might aim for performance, and thus might require a very speed-optimized layout; this has different manufacturing requirements compared to a USB controller, which is built to meet certain USB standards, rather than for processing speed; by having different parts of the overall design separated into different dies, each one optimized in terms of design and manufacturing, the overall yield and cost of the combined die solution may be improved.

The connectivity between these dies is achievable by many ways. For example, in 2.5D packaging solutions, a silicon interposer and through-silicon vias (TSVs) connect dies at silicon interconnect speed in a minimal footprint. In another example, called Embedded Multi-Die Interconnect Bridge (EMIB™), a silicon bridge embedded under the edges of two interconnecting dies facilitates electrical coupling between them. The bridge die may be embedded in a package substrate, facilitating an omni-directional interconnect (ODI™), which allows for top-packaged chips to communicate with other chips horizontally using the bridge die and vertically, using Through-Mold Vias (TMVs) in the package substrate. Such die partitioning enables miniaturization of small form factor and high performance without yield issues seen with other methods but needs fine die-to-die interconnections. The EMIB can facilitate such high-density interconnections by inserting the bridge dies only where needed.

In a related field, microfluidic devices are increasingly being used to perform complex multiplexed reactions, measurements and assays for chemical and biological applications. Microfluidics is the manipulation of fluids at micron-scales and the engineering of devices with very small footprints and channels for fluid flow. In microfluidic channels, fluid flows are laminar, a regime in which viscosity-related effects are more important than inertial ones. Several materials, such as glass, silicon and polymers, are typically employed to manufacture microfluidic devices. Typically, microfluidic devices are manufactured separately from any electronic devices, such as ICs, and the two devices are coupled together by conductive wires to enable, for example, testing (by the microfluidic device) and analysis (by the electronic device). In some cases, ICs and microfluidic devices may be combined to create what is commonly referred to as “lab-on-a-chip” (LOC). Microfluidic technologies used in LOC devices aim to manufacture millions of microchannels, each measuring micrometers, on a single chip; the microchannels enable handling of fluids in quantities as low as a few picoliters as well as the manipulation of biochemical reactions at very small volumes.

Progress in nanotechnology including manufacture of microelectromechanical systems (MEMS) devices is making sophisticated LOC systems, also known as total analysis systems (μTAS), commercially viable. The LOC systems typically employ one or more MEMS devices, which may take a variety of forms, including the form of various microfluidic devices capable of performing operations on small bodies of fluids and/or on particles suspended in a fluid, for example, a colloidal suspension. Microfluidic devices commonly employ fluids such as whole blood samples, bacterial cell suspensions, protein or antibody solutions, and various buffers, and reagents.

Current technologies enable only relatively simple LOC devices (e.g., glucose meters) because of various manufacturing challenges in integrating different physical regimes, such as electronics and fluid dynamics in large scale industrialized production. Besides, even if LOC devices can be small and powerful, they require specific electronics to be able to work properly. Further, it may be advantageous to integrate semiconductor technologies for small form factor and increased functionalities as described above with microfluidic devices in LOC structures for various applications in a variety of fields. However, integrating semiconductor devices with microfluidics in large scale manufacturing facilities has not been adequately addressed with current technologies. Thus, there is still significant room for improvement in the structure of LOC systems, and in the manufacture and operation of such devices.

Accordingly, embodiments described herein enable a microelectronic assembly that includes: an interposer comprising a first portion in contact along an interface with a second portion; a first IC die embedded in a dielectric material in the first portion of the interposer; and a second IC die coupled to the first portion of the interposer opposite to the second portion. The second portion comprises a glass substrate with a channel within the glass substrate, a portion of the channel has an opening at the interface, a conductive pad in the first portion is exposed in the opening, and the conductive pad is coupled to a circuit in at least one of the first IC die or the second IC die.

Some other embodiments of a package substrate comprise a first layer of organic dielectric material, the first layer having a first side and an opposing second side; and a second layer of glass attached to the first side of the first layer. The second layer of glass comprises channels configured for flow of a fluid therethrough, and the first layer comprises bond-pads on the second side configured to be attached to IC dies.

Some embodiments of an interposer disclosed herein comprise: a first layer of organic dielectric material, the first layer having a first side and an opposing second side; and a second layer of glass attached to the first side of the first layer. The second layer of glass comprises microfluidic channels having a linear cross-sectional dimension in a range between approximately 100 nanometers and 500 micrometers, the first layer comprises bond-pads on the second side configured to be attached to IC dies, and the first layer comprises a bridge IC die in the organic dielectric material and TDVs around the bridge IC die, the bridge IC die conductively coupling a subset of the bond-pads on the second side.

Embodiments disclosed herein further include a method, comprising: providing a support structure of glass, plating conductive pads on a first side of the support structure, forming through-glass vias (TGVs) through the glass, the TGVs extending between the first side and an opposite second side of the support structure, etching channels in the glass, the channels being around the TGVs and having openings contiguous with a subset of the conductive pads, depositing organic dielectric material on the first side of the support structure, forming conductive traces, bond-pads, and vias in the organic dielectric material, the bond-pads being on a side of the organic dielectric material opposite to the support structure, and coupling IC dies to the bond-pads.

Each of the structures, assemblies, packages, methods, devices, and systems of the present disclosure may have several innovative aspects, no single one of which is solely responsible for all the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art.

The terms “circuit” and “circuitry” mean one or more passive and/or active electrical and/or electronic components that are arranged to cooperate with one another to provide a desired function. The terms also refer to analog circuitry, digital circuitry, hard wired circuitry, programmable circuitry, microcontroller circuitry and/or any other type of physical hardware electrical and/or electronic component.

The term “integrated circuit” means a circuit that is integrated into a monolithic semiconductor or analogous material.

In some embodiments, the IC dies disclosed herein may comprise substantially monocrystalline semiconductors, such as silicon or germanium, as a base material (e.g., substrate, body) on which integrated circuits are fabricated with traditional semiconductor processing methods. The semiconductor base material may include, for example, N-type pr P-type materials. Dies may include, for example, a crystalline base material formed using a bulk silicon (or other bulk semiconductor material) or a silicon-on-insulator (SOI) structure. In some other embodiments, the base material of one or more of the IC dies may comprise alternate materials, which may or may not be combined with silicon that include but are not limited to germanium, indium antimonide, lead telluride, indium arsenide, indium phosphide, gallium arsenide, indium gallium arsenide, gallium antimonide, or other combinations of group III-N, group III-V, group II-VI, or group IV materials. In yet other embodiments, the base material may comprise compound semiconductors, for example, with a first sub-lattice of at least one element from group III of the periodic table (e.g., Al, Ga, In), and a second sub-lattice of at least one element of group V of the periodic table (e.g., P, As, Sb). In yet other embodiments, the base material may comprise an intrinsic IV or III-V semiconductor material or alloy, not intentionally doped with any electrically active impurity; in alternate embodiments, nominal impurity dopant levels may be present. In still other embodiments, dies may comprise a non-crystalline material, such as polymers; for example, the base material may comprise silica-filled epoxy. In other embodiments, the base material may comprise high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, the base material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphide, and black phosphorus, each of which may possibly be doped with one or more of gallium, indium, aluminum, fluorine, boron, phosphorus, arsenic, nitrogen, tantalum, tungsten, and magnesium, etc. Although a few examples of the material for dies are described here, any material or structure that may serve as a foundation (e.g., base material) upon which IC circuits and structures as described herein may be built falls within the spirit and scope of the present disclosure.

Unless described otherwise, IC dies described herein include one or more IC structures (or, simply, “ICs”) implementing (i.e., configured to perform) certain functionality. In one such example, the term “memory die” may be used to describe a die that includes one or more ICs implementing memory circuitry (e.g., ICs implementing one or more of memory devices, memory arrays, control logic configured to control the memory devices and arrays, etc.). In another such example, the term “compute die” may be used to describe a die that includes one or more ICs implementing logic/compute circuitry (e.g., ICs implementing one or more of I/O functions, arithmetic operations, pipelining of data, etc.).

In another example, the terms “package” and “IC package” are synonymous, as are the terms “die” and “IC die.” Note that the terms “chip,” “die,” and “IC die” are used interchangeably herein.

The term “optical structure” includes arrangements of forms fabricated in ICs to receive, transform and/or transmit optical signals as described herein. It may include optical conductors such as waveguides, electromagnetic radiation sources such as lasers and light-emitting diodes (LEDs) and electro-optical devices such as photodetectors.

In various embodiments, any photonic IC (PIC) described herein may comprise a semiconductor material including, for example, N-type or P-type materials. The PIC may include, for example, a crystalline base material formed using a bulk silicon (or other bulk semiconductor material) or a SOI structure (or, in general, a semiconductor-on-insulator structure). In some embodiments, the PIC may be formed using alternative materials, which may or may not be combined with silicon, that include, but are not limited to, lithium niobite, indium phosphide, silicon dioxide, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-N or group IV materials. In some embodiments, the PIC may comprise a non-crystalline material, such as polymers. In some embodiments, the PIC may be formed on a printed circuit board (PCB). In some embodiments, the PIC may be inhomogeneous, including a carrier material (such as glass or silicon carbide) as a base material with a thin semiconductor layer over which is an active side comprising transistors and like components. Although a few examples of the material for the PIC are described here, any material or structure that may serve as a foundation upon which the PIC may be built falls within the spirit and scope of the present disclosure.

The term “insulating” means “electrically insulating,” the term “conducting” means “electrically conducting,” unless otherwise specified. With reference to optical signals and/or devices, components and elements that operate on or using optical signals, the term “conducting” can also mean “optically conducting.”

The terms “oxide,” “carbide,” “nitride,” etc. refer to compounds containing, respectively, oxygen, carbon, nitrogen, etc.

The term “high-k dielectric” refers to a material having a higher dielectric constant than silicon oxide, while the term “low-k dielectric” refers to a material having a lower dielectric constant than silicon oxide.

The term “insulating material” or “insulator” (also called herein as “dielectric material” or “dielectric”) refers to solid materials (and/or liquid materials that solidify after processing as described herein) that are substantially electrically nonconducting. They may include, as examples and not as limitations, organic polymers and plastics, and inorganic materials such as ionic crystals, porcelain, glass, silicon, silicon oxide, silicon carbide, silicon carbonitride, silicon nitride, and alumina or a combination thereof. They may include dielectric materials, high polarizability materials, and/or piezoelectric materials. They may be transparent or opaque without departing from the scope of the present disclosure. Further examples of insulating materials are underfills and molds or mold-like materials used in packaging applications, including for example, materials used in organic interposers, package supports and other such components.

In various embodiments, elements associated with an IC may include, for example, transistors, diodes, power sources, resistors, capacitors, inductors, sensors, transceivers, receivers, antennas, etc. In various embodiments, elements associated with an IC may include those that are monolithically integrated within an IC, mounted on an IC, or those connected to an IC. The ICs described herein may be either analog or digital and may be used in a number of applications, such as microprocessors, optoelectronics, logic blocks, audio amplifiers, etc., depending on the components associated with the IC. The ICs described herein may be employed in a single IC die or as part of a chipset for executing one or more related functions in a computer.

In various embodiments of the present disclosure, transistors described herein may be field effect transistors (FETs), e.g., MOSFETs. In many embodiments, an FET is a four-terminal device. In SOI, or nanoribbon, or gate all-around (GAA) FET, the FET is a three-terminal device that includes source, drain, and gate terminals and uses electric field to control current flowing through the device. A FET typically includes a channel material, a source region and a drain regions provided in and/or over the channel material, and a gate stack that includes a gate electrode material, alternatively referred to as a “work function” material, provided over a portion of the channel material (the “channel portion”) between the source and the drain regions, and optionally, also includes a gate dielectric material between the gate electrode material and the channel material.

In a general sense, an “interconnect” refers to any element that provides a physical connection between two other elements. For example, an electrical interconnect provides electrical connectivity between two electrical components, facilitating communication of electrical signals between them; an optical interconnect provides optical connectivity between two optical components, facilitating communication of optical signals between them. As used herein, both electrical interconnects and optical interconnects are comprised in the term “interconnect.” The nature of the interconnect being described is to be understood herein with reference to the signal medium associated therewith. Thus, when used with reference to an electronic device, such as an IC that operates using electrical signals, the term “interconnect” describes any element formed of an electrically conductive material for providing electrical connectivity to one or more elements associated with the IC or/and between various such elements. In such cases, the term “interconnect” may refer to both conductive traces (also sometimes referred to as “lines,” “wires,” “metal lines” or “trenches”) and conductive vias (also sometimes referred to as “vias” or “metal vias”). Sometimes, electrically conductive traces and vias may be referred to as “conductive traces” and “conductive vias”, respectively, to highlight the fact that these elements include electrically conductive materials such as metals. Likewise, when used with reference to a device that operates on optical signals as well, such as a photonic IC (PIC), “interconnect” may also describe any element formed of a material that is optically conductive for providing optical connectivity to one or more elements associated with the PCI. In such cases, the term “interconnect” may refer to optical waveguides, including optical fiber, optical splitters, optical combiners, optical couplers, and optical vias.

The term “waveguide” refers to any structure that acts to guide the propagation of light from one location to another location typically through a substrate material such as silicon or glass. In various examples, waveguides can be formed from silicon, doped silicon, silicon nitride, glasses such as silica (e.g., silicon dioxide or SiO₂), borosilicate (e.g., 70-80 wt % SiO₂, 7-13 wt % of B₂O₃, 4-8 wt % Na₂O or K₂O, and 2-8 wt % of Al₂O₃) and so forth. Waveguides may be formed using various techniques including but not limited to forming waveguides in situ. For example, in some embodiments, waveguides may be formed in situ in glass using low temperature glass-to-glass bonding or by laser direct writing. Waveguides formed in situ may have lower loss characteristics.

The term “conductive trace” may be used to describe an electrically conductive element isolated by an insulating material. Within IC dies, such insulating material comprises interlayer low-k dielectric that is provided within the IC die. Within package substrates, and PCBs such insulating material comprises organic materials such as Ajinomoto Buildup Film (ABF), polyimides, or epoxy resin. Such conductive lines are typically arranged in several levels, or several layers, of metallization stacks.

The term “conductive via” may be used to describe an electrically conductive element that interconnects two or more conductive lines of different levels of a metallization stack. To that end, a via may be provided substantially perpendicularly to the plane of an IC die/chip or a support structure over which an IC structure is provided and may interconnect two conductive lines in adjacent levels or two conductive lines in non-adjacent levels.

The term “package substrate” may be used to describe any substrate material that facilitates the packaging together of any collection of semiconductor dies and/or other electrical components such as passive electrical components. As used herein, a package substrate may be formed of any material including, but not limited to, insulating materials such as resin impregnated glass fibers (e.g., PCB or Printed Wiring Boards (PWB)), glass, ceramic, silicon, silicon carbide, etc. In addition, as used herein, a package substrate may refer to a substrate that includes buildup layers (e.g., ABF layers).

The term “metallization stack” may be used to refer to a stack of one or more interconnects for providing connectivity to different circuit components of an IC die/chip and/or a package substrate.

As used herein, the term “pitch” of interconnects refers to a center-to-center distance between adjacent interconnects.

In context of a stack of dies coupled to one another or in context of a die coupled to a package substrate, the term “interconnect” may also refer to, respectively, die-to-die (DTD) interconnects and die-to-package substrate (DTPS) interconnects. DTD interconnects may also be referred to as first-level interconnects (FLI). DTPS interconnects may also be referred to as Second-Level Interconnects (SLI).

Although not specifically shown in all of the present illustrations in order to not clutter the drawings, when DTD or DTPS interconnects are described, a surface of a first die may include a first set of conductive contacts, and a surface of a second die or a package substrate may include a second set of conductive contacts. One or more conductive contacts of the first set may then be electrically and mechanically coupled to some of the conductive contacts of the second set by the DTD or DTPS interconnects.

In some embodiments, the pitch of the DTD interconnects may be different from the pitch of the DTPS interconnects, although, in other embodiments, these pitches may be substantially the same.

The DTPS interconnects disclosed herein may take any suitable form. In some embodiments, a set of DTPS interconnects may include solder (e.g., solder bumps or balls that are subject to a thermal reflow to form the DTPS interconnects). DTPS interconnects that include solder may include any appropriate solder material, such as lead/tin, tin/bismuth, eutectic tin/silver, ternary tin/silver/copper, eutectic tin/copper, tin/nickel/copper, tin/bismuth/copper, tin/indium/copper, tin/zinc/indium/bismuth, or other alloys. In some embodiments, a set of DTPS interconnects may include an anisotropic conductive material, such as an anisotropic conductive film or an anisotropic conductive paste. An anisotropic conductive material may include conductive materials dispersed in a non-conductive material. In some embodiments, an anisotropic conductive material may include microscopic conductive particles embedded in a binder or a thermoset adhesive film (e.g., a thermoset biphenyl-type epoxy resin, or an acrylic-based material). In some embodiments, the conductive particles may include a polymer and/or one or more metals (e.g., nickel or gold). For example, the conductive particles may include nickel-coated gold or silver-coated copper that is in turn coated with a polymer. In another example, the conductive particles may include nickel. When an anisotropic conductive material is uncompressed, there may be no conductive pathway from one side of the material to the other. However, when the anisotropic conductive material is adequately compressed (e.g., by conductive contacts on either side of the anisotropic conductive material), the conductive materials near the region of compression may contact each other so as to form a conductive pathway from one side of the film to the other in the region of compression.

The DTD interconnects disclosed herein may take any suitable form. In some embodiments, some or all of the DTD interconnects in a microelectronic assembly or an IC package as described herein may be metal-to-metal interconnects (e.g., copper-to-copper interconnects, or plated interconnects). In such embodiments, the conductive contacts on either side of the DTD interconnect may be bonded together (e.g., under elevated pressure and/or temperature) without the use of intervening solder or an anisotropic conductive material. In some metal-to-metal interconnects, a dielectric material (e.g., silicon oxide, silicon nitride, silicon carbide) may be present between the metals bonded together (e.g., between copper pads or posts that provide the associated conductive contacts). In some embodiments, one side of a DTD interconnect may include a metal pillar (e.g., a copper pillar), and the other side of the DTD interconnect may include a metal contact (e.g., a copper contact) recessed in a dielectric. In some embodiments, a metal-to-metal interconnect (e.g., a copper-to-copper interconnect) may include a noble metal (e.g., gold) or a metal whose oxides are conductive (e.g., silver). In some embodiments, a metal-to-metal interconnect may include metal nanostructures (e.g., nanorods) that may have a reduced melting point. Metal-to-metal interconnects may be capable of reliably conducting a higher current than other types of interconnects; for example, some solder interconnects may form brittle intermetallic compounds when current flows, and the maximum current provided through such interconnects may be constrained to mitigate mechanical failure.

In some embodiments, the dies on either side of a set of DTD interconnects may be bare (e.g., unpackaged) dies.

In some embodiments, the DTD interconnects may include solder. For example, the DTD interconnects may include conductive bumps or pillars (e.g., copper bumps or pillars) attached to the respective conductive contacts by solder. In some embodiments, a thin cap of solder may be used in a metal-to-metal interconnect to accommodate planarity, and this solder may become an intermetallic compound during processing. In some embodiments, the solder used in some or all of the DTD interconnects may have a higher melting point than the solder included in some or all of the DTPS interconnects. For example, when the DTD interconnects in an IC package are formed before the DTPS interconnects are formed, solder-based DTD interconnects may use a higher-temperature solder (e.g., with a melting point above 200 degrees Celsius), while the DTPS interconnects may use a lower-temperature solder (e.g., with a melting point below 200 degrees Celsius). In some embodiments, a higher-temperature solder may include tin; tin and gold; or tin, silver, and copper (e.g., 96.5% tin, 3% silver, and 0.5% copper). In some embodiments, a lower-temperature solder may include tin and bismuth (e.g., eutectic tin bismuth), tin, silver, bismuth, indium, indium and tin, or gallium.

In some embodiments, a set of DTD interconnects may include an anisotropic conductive material, such as any of the materials discussed above for the DTPS interconnects. In some embodiments, the DTD interconnects may be used as data transfer lanes, while the DTPS interconnects may be used for power and ground lines, among others.

In microelectronic assemblies or IC packages as described herein, some or all of the DTD interconnects may have a finer pitch than the DTPS interconnects. In some embodiments, the DTPS interconnects disclosed herein may have a pitch between about 80 microns and 300 microns, while the DTD interconnects disclosed herein may have a pitch between about 0.5 microns and 100 microns, depending on the type of the DTD interconnects. An example of silicon-level interconnect density is provided by the density of some DTD interconnects. In some embodiments, the DTD interconnects may have too fine a pitch to couple to the package substrate directly (e.g., too fine to serve as DTPS interconnects). The DTD interconnects may have a smaller pitch than the DTPS interconnects due to the greater similarity of materials in the different dies on either side of a set of DTD interconnects than between a die and a package substrate on either side of a set of DTPS interconnects. In particular, the differences in the material composition of dies and package substrates may result in differential expansion and contraction of the die dies and package substrates due to heat generated during operation (as well as the heat applied during various manufacturing operations). To mitigate damage caused by this differential expansion and contraction (e.g., cracking, solder bridging, etc.), the DTPS interconnects in any of the microelectronic assemblies or IC packages as described herein may be formed larger and farther apart than DTD interconnects, which may experience less thermal stress due to the greater material similarity of the pair of dies on either side of the DTD interconnects.

It will be recognized that one more levels of underfill (e.g., organic polymer material such as benzotriazole, imidazole, polyimide, or epoxy) may be provided in an IC package described herein and may not be labeled in order to avoid cluttering the drawings. In various embodiments, the levels of underfill may comprise the same or different insulating materials. In some embodiments, the levels of underfill may comprise thermoset epoxies with silicon oxide particles; in some embodiments, the levels of underfill may comprise any suitable material that can perform underfill functions such as supporting the dies and reducing thermal stress on interconnects. In some embodiments, the choice of underfill material may be based on design considerations, such as form factor, size, stress, operating conditions, etc.; in other embodiments, the choice of underfill material may be based on material properties and processing conditions, such as cure temperature, glass transition temperature, viscosity and chemical resistance, among other factors; in some embodiments, the choice of underfill material may be based on both design and processing considerations.

In some embodiments, one or more levels of solder resist (e.g., epoxy liquid, liquid photo-imageable polymers, dry film photo-imageable polymers, acrylics, solvents) may be provided in an IC package described herein and may not be labeled or shown to avoid cluttering the drawings. Solder resist may be a liquid or dry film material including photo-imageable polymers. In some embodiments, solder resist may be non-photo-imageable.

The terms “substantially,” “close,” “approximately,” “near,” and “about,” generally refer to being within +/−20% of a target value (e.g., within +/−5% or 10% of a target value) based on the context of a particular value as described herein or as known in the art.

Terms indicating orientation of various elements, e.g., “coplanar,” “perpendicular,” “orthogonal,” “parallel,” or any other angle between the elements, generally refer to being within +/−5%-20% of a target value based on the context of a particular value as described herein or as known in the art.

The term “connected” means a direct connection (which may be one or more of a mechanical, electrical, and/or thermal connection) between the things that are connected, without any intermediary devices, while the term “coupled” means either a direct connection between the things that are connected, or an indirect connection through one or more passive or active intermediary devices.

The description uses the phrases “in an embodiment” or “in embodiments,” which may each refer to one or more of the same or different embodiments.

Furthermore, the terms “comprising,” “including,” “having,” and the like, as used with respect to embodiments of the present disclosure, are synonymous.

The disclosure may use perspective-based descriptions such as “above,” “below,” “top,” “bottom,” and “side”; such descriptions are used to facilitate the discussion and are not intended to restrict the application of disclosed embodiments.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with one or both of the two layers or may have one or more intervening layers. In contrast, a first layer described to be “on” a second layer refers to a layer that is in direct contact with that second layer. Similarly, unless explicitly stated otherwise, one feature disposed between two features may be in direct contact with the adjacent features or may have one or more intervening layers.

The term “dispose” as used herein refers to position, location, placement, and/or arrangement rather than to any particular method of formation.

The term “between,” when used with reference to measurement ranges, is inclusive of the ends of the measurement ranges.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). When used herein, the notation “A/B/C” means (A), (B), and/or (C).

Although certain elements may be referred to in the singular herein, such elements may include multiple sub-elements. For example, “an electrically conductive material” may include one or more electrically conductive materials. In another example, “a dielectric material” may include one or more dielectric materials.

Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

The accompanying drawings are not necessarily drawn to scale.

In the drawings, same reference numerals refer to the same or analogous elements/materials shown so that, unless stated otherwise, explanations of an element/material with a given reference numeral provided in context of one of the drawings are applicable to other drawings where element/materials with the same reference numerals may be illustrated. Further, the singular and plural forms of the labels may be used with reference numerals to denote a single one and multiple ones respectively of the same or analogous type, species, or class of element.

Furthermore, in the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using, e.g., images of suitable characterization tools such as scanning electron microscopy (SEM) images, transmission electron microscope (TEM) images, or non-contact profilometer. In such images of real structures, possible processing and/or surface defects could also be visible, e.g., surface roughness, curvature or profile deviation, pit or scratches, not-perfectly straight edges of materials, tapered vias or other openings, inadvertent rounding of corners or variations in thicknesses of different material layers, occasional screw, edge, or combination dislocations within the crystalline region(s), and/or occasional dislocation defects of single atoms or clusters of atoms. There may be other defects not listed here but that are common within the field of device fabrication and/or packaging.

Note that in the figures, various components (e.g., interconnects) are shown as aligned (e.g., at respective interfaces) merely for ease of illustration; in actuality, some or all of them may be misaligned. In addition, there may be other components, such as bond-pads, landing pads, metallization, etc. present in the assembly that are not shown in the figures to prevent cluttering. Further, the figures are intended to show relative arrangements of the components within their assemblies, and, in general, such assemblies may include other components that are not illustrated (e.g., various interfacial layers or various other components related to optical functionality, electrical connectivity, or thermal mitigation). For example, in some further embodiments, the assembly as shown in the figures may include more dies along with other electrical components. Additionally, although some components of the assemblies are illustrated in the figures as being planar rectangles or formed of rectangular solids, this is simply for ease of illustration, and embodiments of these assemblies may be curved, rounded, or otherwise irregularly shaped as dictated by and sometimes inevitable due to the manufacturing processes used to fabricate various components.

In the drawings, a particular number and arrangement of structures and components are presented for illustrative purposes and any desired number or arrangement of such structures and components may be present in various embodiments.

Further, unless otherwise specified, the structures shown in the figures may take any suitable form or shape according to material properties, fabrication processes, and operating conditions.

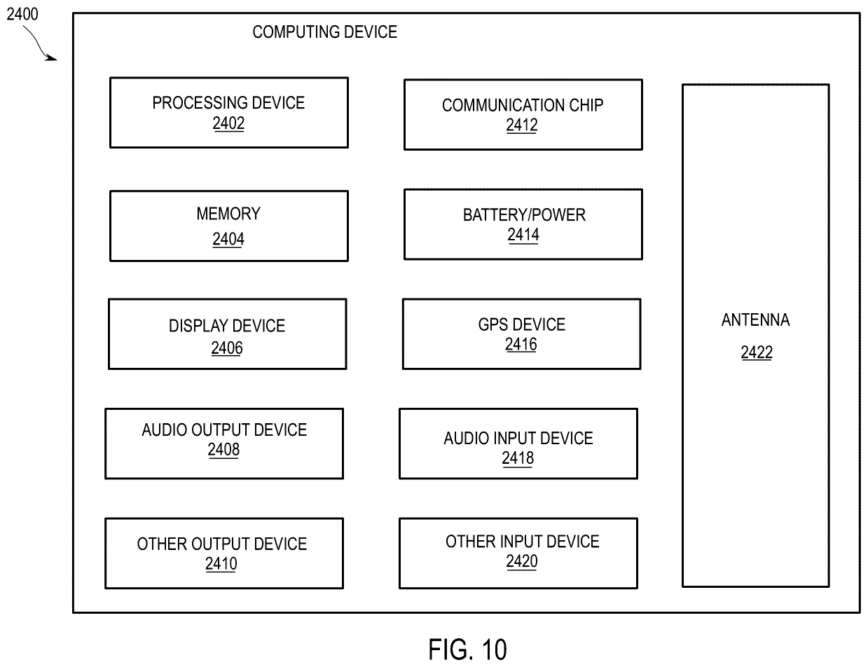

For convenience, if a collection of drawings designated with different letters are present (e.g., FIGS. 10A-10C), such a collection may be referred to herein without the letters (e.g., as “FIG. 10”). Similarly, if a collection of reference numerals designated with different letters are present (e.g., 112a-112e), such a collection may be referred to herein without the letters (e.g., as “112”).

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

### EXAMPLE EMBODIMENTS

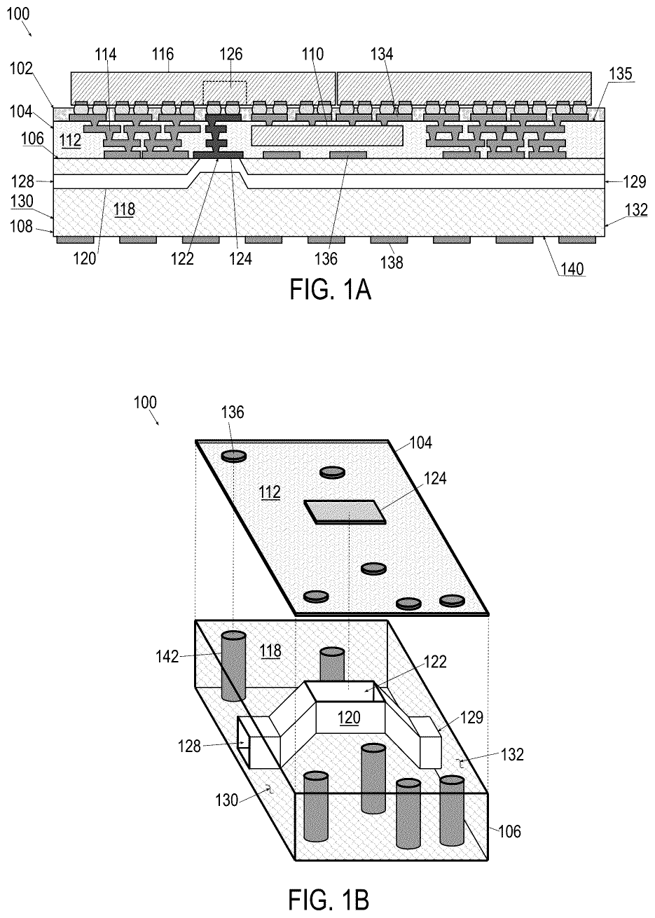

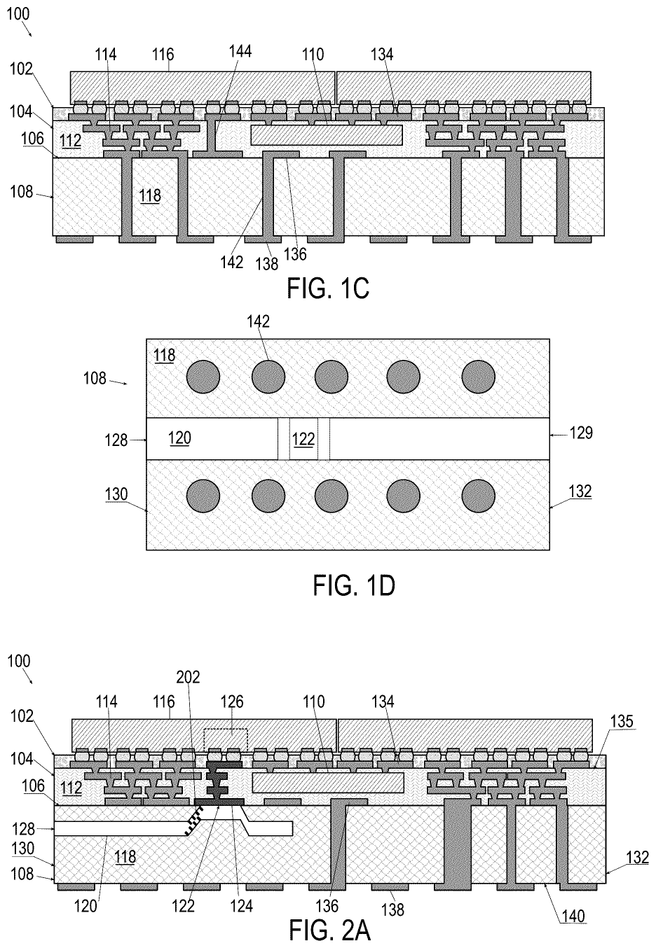

FIG. 1A is a schematic cross-sectional view of an example microelectronic assembly 100 according to some embodiments of the present disclosure. Microelectronic assembly 100 comprises an interposer 102 having a first portion 104 in contact along an interface 106 with a second portion 108. An IC die 110 may be embedded in a dielectric material 112 in first portion 104 of interposer 102. In various embodiments, dielectric material 112 may comprise an organic dielectric material as listed in the previous subsection in reference to package substrates. In other embodiments, dielectric material 112 may comprise an inorganic material, such as silicon oxide, silicon nitride, silicon carbide, silicon oxynitride, silicon oxycarbide, etc. In various embodiments, conductive traces 114 (including conductive vias) may be provisioned in various layers of dielectric material 112, providing conductive pathways from one or more IC die 116 to second portion 108. IC dies 116 may be coupled to first portion 104 of interposer 102 opposite to second portion 108.

In various embodiments, second portion 108 of interposer 102 comprises a glass substrate 118 with a channel 120 within glass substrate 118. In various embodiments, glass substrate 118 may comprise any suitable type of glass, including soda-lime glass, borosilicate glass, aluminosilicate glass, and fused silica glass that is compatible with semiconductor processing, including laser direct writing, lithography, etc. In some embodiments, the glass may comprise borosilicate glass comprising silica (e.g., 52%-56%), alumina (e.g., 12%-16%), borate (e.g., 5%-10%), calcinate (e.g., 16%-25%), and magnesium oxide (e.g., 0%-6%). In some embodiments, the glass may have a composition to enable a low coefficient of thermal expansion (CTE), for example, around 2.8 PPM/C; in some such embodiments, the glass may comprise approximately 60%-65% silica and 20%-25% alumina. In some other embodiments, the glass may have a composition to enable low electrical loss, for example, with dielectric constant around 4.8 at 1 GHz and 4.69 at 10 GHz, and loss tangent of 0.0043 at 1 GHz; in some such embodiments, the glass may comprise approximately 52%-56% silica, 10%-15% alumina, 15%-20% borate, 0%-10% calcinate, and 0%-5% magnesium oxide. Channel 120 is a hollow space in glass substrate 118, providing a pathway for flow of a suitable fluid, such as a gas, liquid coolant, or analyte solution. A portion of channel 120 may have an opening 122 at interface 106. A conductive pad 124 in first portion 104 of interposer 102 is exposed into channel 120 in opening 122. Conductive pad 124 may be coupled to a circuit 126 in at least one of IC dies 110 or 116 by conductive traces 114. In various embodiments, channel 120 may function as a microfluidic channel with a linear dimension of a cross-section (i.e., width or thickness) in a range between approximately 100 nanometers and 500 micrometers. In some embodiments, the linear dimension may be approximately 10 micrometers. Channel 120 may have a portion separated from interface 106 by glass 118. Another portion may be in contact with interface 106 and opening 122 may be in the portion in contact with interface 106. The two portions may be coupled by sloping channels suitably.

In some embodiments, circuit 126 may generate heat during operation. The heat may be conducted away from circuit 126 by conductive traces 114 to conductive pad 124. A liquid coolant (e.g., halocarbon oils, heavy carbon oils, alkene glycols) may be circulated through channel 120. The liquid coolant may transfer the heat away from conductive pad 124. In such embodiments, circuit 126 may comprise a thermal circuit. In some embodiments, circuit 126 may be configured to detect the presence of a substance in channel 120. For example, a gas (e.g., hydrogen) may be forced to flow (e.g., pumped) through channel 120. The gas may contact conductive pad 124 at opening 122. Conductive pad 124 may be a part of a sensor. The presence the gas in contact with conductive pad 124 may cause a change in electrical properties of conductive pad 124 or change in electric current through conductive pad 124 or change in voltage across conductive pad 124. The change may be detected by circuit 126, alerting to the presence of the gas. In some other embodiments, a ligand solution may be pumped through channel 120. Ligands may attach to conductive pad 124 exposed through opening 122. Conductive pad 124 may be conductively coupled to circuit 126 by conductive traces 114. An analyte solution containing biological molecules may be pumped through channel 120 subsequently. The biological molecules may bind to the ligands, changing electrical characteristics (e.g., resistance, current, voltage) of conductive pad 124. The change may be detected by circuit 126, alerting to the presence of the biological molecules. Various other such LOC and microfluidic applications are also contemplated within the broad scope of the embodiments. Note that although only one channel 120 is shown, any number of channels 120 may be provisioned in interposer 102 within the broad scope of the embodiments.

In many embodiments, channel 120 may have a first opening 128 and a second opening 129. First opening 128 may be configured for entry of a fluid; second opening 129 may be configured for exit of the fluid. In the embodiment shown in the figure, first opening 128 is on side 130 and second opening 129 is on side 132. Bond-pads 134 may be configured on one surface 135 of interposer 102. IC dies 116 may be coupled to bond-pads 134 by suitable interconnects, for example, FLIs or SLIs. Conductive traces 114 in and through dielectric 112 may conductively couple bond-pads 134 with bond-pads 136 at interface 106. In various embodiments, bond-pads 138 may be provisioned on side 140 of interposer 102. Bond-pads 138 may be configured to couple to bond-pads 136 by appropriate TGVs 142, as shown in FIG. 1B.

FIG. 1B is a schematic exploded perspective view of the portion of microelectronic assembly 100 of FIG. 1A. A portion of first portion 104 is shown separated from underlying second portion 108. Conductive pad 124 is provisioned in first portion 104, with at least a portion thereof aligned with opening 122. An underlying surface of conductive pad 124 (i.e., opposite to IC dies 116) may be exposed in opening 122. In some embodiments, a partial area of the surface of conductive pad 124 may be exposed in opening 122; in some other embodiments, the entirety of the surface of conductive pad 124 may be exposed in opening 122. In various embodiments, bond-pads 136 may be directly attached to TGVs 142. TGVs 142 may be provisioned around channel 120 in various embodiments. In other embodiments, channel 120 may be formed after TGVs 142 are fabricated, so that channel 120 winds around TGVs 142.

FIG. 1C is a schematic cross-sectional view of another portion of microelectronic assembly of FIG. 1A, the cross-section being spaced away from channel 120 to show TGVs 142 in more detail. Thus, FIGS. 1A and 1C show two separate, parallel cross-sections of the same microelectronic assembly 100. As shown in the figure, TGVs 142 conductively couple bond-pads 136 on interface 106 with bond-pads 138 on side 140 of interposer 102. In some embodiments, bond-pads 134 and 136 may be conductively coupled by through-dielectric vias (TDVs) 144. TDVs 144 differ from the vias of conductive traces 114 in that they do not couple to any conductive traces but instead, each one is a unitary structure between bond-pads 134 and 136. In some embodiments, TDVs 144 may conductively couple to TGVs 142.

FIG. 1D is a schematic plan view of a portion of microelectronic assembly of FIG. 1A. In the embodiment shown in the figure, channel 120 extends from side 130 to opposite side 132, with entry opening 128 on side 130 and exit opening 129 on side 132.

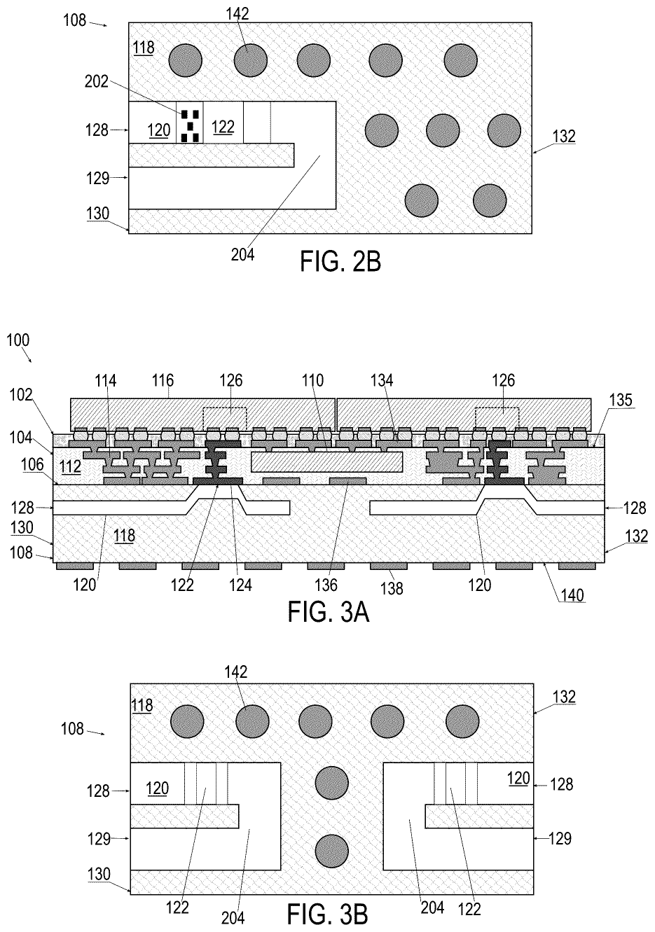

FIG. 2A is a schematic cross-sectional view of an example microelectronic assembly according to another embodiment of the present disclosure. The embodiment shown in the figure is substantially similar to that of FIG. 1A, except that channel 120 is curved or bent, so that it does not extend from side 130 to side 132. Instead, both entry opening 128 and exit opening 129 are on common side 130.

In the embodiment shown in the figure, baffles 202 are provisioned in a portion of channel 120 between entry opening 128 and opening 122 through which conductive pad 124 is exposed. In some embodiments, baffles 202 may be provisioned between opening 122 and exit opening 129 also. In some embodiments, baffles 202 may permit cavitation free flow of the fluid through channel 120, allowing, for example, more time for substances to collect around conductive pad 124 for enhanced detectability.

FIG. 2B is a schematic plan view of a portion of microelectronic assembly of FIG. 2A. Channel 120 has a bend 204 so that entry opening 128 and exit opening 129 are on common side 130. Note that baffles 202 may be provisioned thus in other embodiments of the present disclosure, including embodiments shown in FIG. 1A, 3A, etc.

FIG. 3A is a schematic cross-sectional view of an example microelectronic assembly according to another embodiment of the present disclosure. The embodiment shown in the figure is substantially similar to that of FIG. 2A, except that additional channels 120 may be provisioned such that openings 128 and 129 are on side 132. In the embodiment shown in the figure, a subset of channels 120 have openings on side 130 and another subset of channels have openings of side 132. Some other subset of channels 120 (not shown) may extend between sides 130 and 132 or sides orthogonal to these sides (out of plane of the page). In some embodiments (not shown), channel 120 may be bent such that openings 128 and 129 are on mutually orthogonal sides.

FIG. 3B is a schematic plan view of a portion of microelectronic assembly of FIG. 2A, showing openings 128 and 129 on side 130 in some channels 120 and on side 132 in other channels 120.

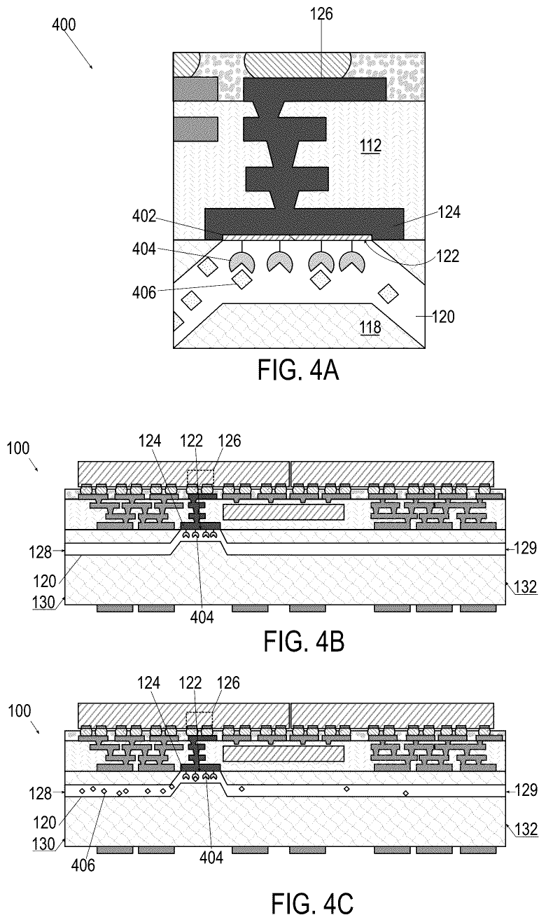

FIG. 4A shows a detail 400 of a cross-section around conductive pad 124 in microelectronic assembly 100 according to some embodiments of the present disclosure. Conductive pad 124 may have a coating 402 on a surface of conductive pad 124 exposed in opening 122. In various embodiments, coating 402 may comprise gold. Ligands 404 may be attached to coating 402 in opening 122. Biological molecules 406 in channel 120 may bind to ligands 404. As used herein, a “ligand” refers to a molecule or atom that binds to a receiving biological molecule, such as biological molecule 406, which may function as a receptor when bound thus. Examples of ligands include alkylcarboxylic acids, alkanethiolds, aminethiols, alkyl amines, and hydrophilic polymers like polydimethylsiloxanes or vinyls. Examples of biological molecules 406 include protein molecules, enzymes, deoxyribonucleic/ribonucleic acid, hormones, and other molecules synthesized by biological organisms. In general, when ligand 404 binds to its respective receptor (i.e., biological molecule 406), the shape and/or activity of ligand 404 is altered to initiate several different types of responses. In one such response, the electrical characteristics (e.g., resistance, current, voltage) of conductive pad 124 may be altered. The change may be detected by circuit 126 alerting circuit 126 to the presence of biological molecules 406 in channel 120.

Although only one type of ligands 404 is shown, any number of ligands may be attached to conductive pad 124 by suitably tailoring the flow characteristics of the fluid in channel 120. In some embodiments, a single conductive pad 124 may be used to attach multiple ligands 404 and detect correspondingly different biological molecules 406. In some other embodiments, a plurality of conductive pads 124 may be provisioned with different ligands 404, each one of ligands 404 attached to separate ones of conductive pads 124.

FIG. 4B shows a simplified cross-sectional view of microelectronic assembly 100 after ligands 404 are attached to conductive pad 124. In various embodiments, a solution containing ligands 404 may be pumped through channel 120. Ligands 404 may have an affinity for coating 402 and may attach to coating 402 upon contact.

FIG. 4C shows a simplified cross-sectional view of microelectronic assembly 100 after an analyte solution comprising biological molecules 406 is pumped through channel 120. Biological molecules 406 in the analyte solution may bind to ligands 404, altering electrical characteristics of conductive pad 124 in opening 122. Circuit 126 may detect the presence of biological molecules 406 from the change in electrical characteristics of conductive pad 124.

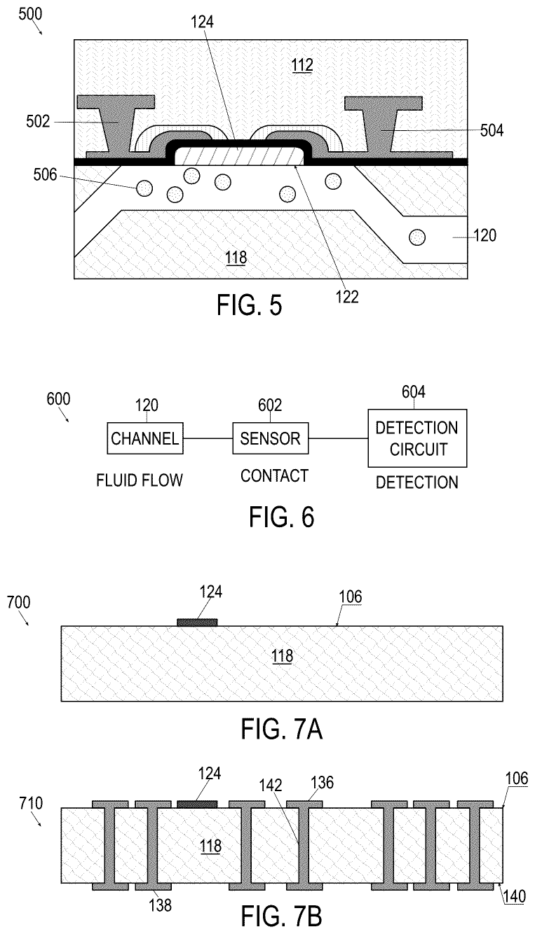

FIG. 5 shows a detail 500 of a cross-section around conductive pad 124 in microelectronic assembly 100 according to some embodiments of the present disclosure. Conductive pad 124 may be a central pad of gold of a sensor configured to detect hydrogen gas in channel 120. The sensor may comprise a conductive trace 502 (including via) at a drain voltage (e.g., 0.01-12V) on one side of conductive pad 124 and another conductive trace 504 (including via) at a source voltage (e.g., 0.01-12V) on an opposing side of conductive pad 124. Conductive pad 124 may be at a gate voltage (e.g., 0.01-12V). Gas comprising hydrogen molecules 506 (shown much larger than scale) may be pumped through channel 120. When hydrogen molecules 506 contact exposed surface of conductive pad 124, a differential current may flow between conductive traces 502 and 504, causing circuit 126 (not shown) to register the presence of hydrogen in channel 120. Such techniques may find use in monitoring exhaust or other gaseous byproducts from automobiles. In some such embodiments, microelectronic assembly 100 may be part of a control system of an automobile. By providing in situ detection of the components of the gas in channel 120 by circuit 126, faster response times may be achieved than where LOC components are separated into different devices.

FIG. 6 is a simplified block diagram illustrating example components 600 of microelectronic assembly 100. Channel 120 may facilitate fluid flow in portion 108 of interposer 102. A sensor 602 may contact the fluid flowing through channel 120. In various embodiments, sensor 602 may comprise conductive pad 124 (among other components). In some embodiments, sensor 602 may comprise a combination of conductive pad 124 and ligands 404. A detection circuit 604 may facilitate detecting various substances in the fluid flowing through channel 120. Detection circuit 604 in some embodiments may comprise circuit 126. In other embodiments, detection circuit 604 may comprise a plurality of circuits including circuit 126.

In various embodiments, any of the features discussed with reference to any of FIGS. 1-6 herein may be combined with any other features to form a package with one or more IC dies as described herein. For example, in some embodiments, IC die 110 functioning as a bridge IC die may be absent; in other embodiments, only one of IC dies 116 may be present. Some such combinations are described above, but, in various embodiments, further combinations and modifications are possible. Various different embodiments described in different figures may be combined suitably based on particular needs within the broad scope of the embodiments.

### Example Methods

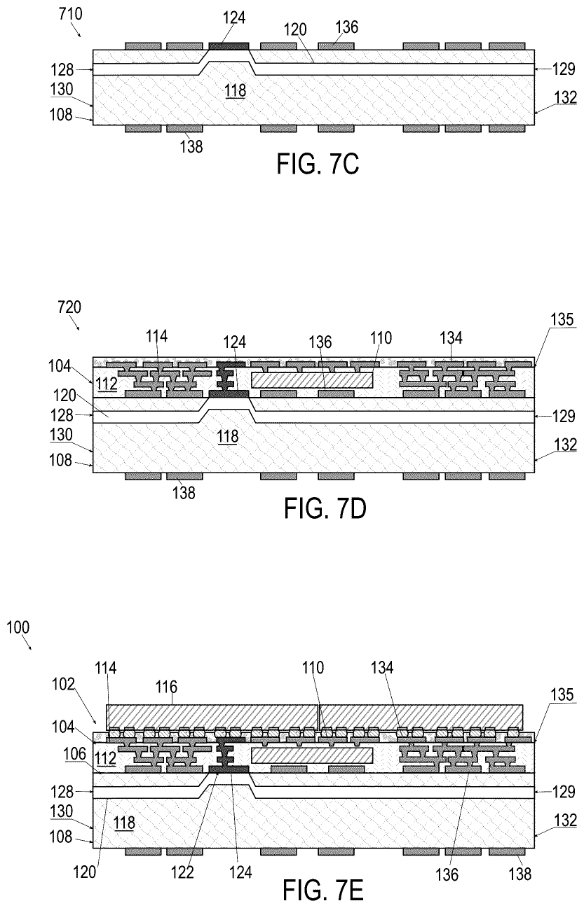

FIGS. 7A-7E are schematic cross-sectional views of portions of microelectronic assembly 100 at various stages of manufacture according to some embodiments of the present disclosure. FIG. 7A shows a support structure 700 comprising glass substrate 118. In some embodiments, support structure 700 may comprise a panel of glass, for example, measuring 600 millimeters by 600 millimeters or smaller, based on particular needs beyond the scope of the present disclosure. Conductive pad 124 may be plated on interface 106 of glass substrate 118, which is a surface at this stage of manufacture. In some embodiments, conductive pad 124 may comprise gold. In other embodiments, conductive pad 124 may comprise copper. The particular material of conductive pad 124 may be chosen based on the application to which microelectronic assembly 100 may be put to use.

FIG. 7B shows a structure 710 subsequent to forming additional bond-pads 136 and 138 on interface 106 and side 140 respectively of glass substrate 118. TGVs 142 may also be formed to conductively couple bond-pads 136 and 138 suitably. In various embodiments, TGVs may be formed by laser drilling through holes through glass substrate 118, followed by electroplating to form bond-pads 136, 138 and TGVs 142. In some embodiments, the through-hole may be filled with conductive material before forming bond-pads 136 and 138.

FIG. 7C shows another view of structure 710, in which channel 120 is visible. Channel 120 may be formed by laser direct writing (LDW) in some embodiments. In other embodiments, a sodium hydroxide (NaOH) etch may be used to form suitably shaped channel 120. Opening 122 may be formed concurrently as the remaining portion of channel 120. At the end of the process illustrated by FIGS. 7B and 7C, portion 108 of interposer 102 may be complete.

FIG. 7D shows a structure 720 subsequent to forming portion 104 of interposer 102. Layers of organic dielectric material 112 may be deposited on interface 106 of glass substrate 118, which is a surface at this stage of manufacture. Conductive traces 114 may be formed therein by sequential electroplating processes alternating with organic dielectric material deposition. In some embodiments, IC die 110 may be embedded in organic dielectric material 112 by processes known in the art (e.g., forming a cavity, attached IC die 110 using a die attach adhesive, overmolding with organic dielectric material 112, etc.). Bond-pads 134 may be formed on surface 135. A layer of solder resist may be deposited in some embodiments where solder interconnects are used to attach IC dies 116. At the end of these operations, interposer 102 may be substantially complete.

FIG. 7E shows microelectronic assembly 100 subsequent to attaching IC dies 116 and singulating into individual units. In the embodiment shown in the figure, IC dies 116 are attached using solder interconnects (e.g., flip-chips). Any suitable DTD interconnects or other FLIs or SLIs may be used within the broad scope of the embodiments.

Although FIGS. 7A-7E illustrate various operations performed in a particular order, this is simply illustrative, and the operations discussed herein may be reordered and/or repeated as suitable. Further, additional processes which are not illustrated may also be performed without departing from the scope of the present disclosure. Also, various ones of the operations discussed herein with respect to FIGS. 7A-7E may be modified in accordance with the present disclosure to fabricate others of microelectronic assembly 100 disclosed herein. Although various operations are illustrated in FIGS. 7A-7E once each, the operations may be repeated as often as desired. For example, one or more operations may be performed in parallel to manufacture and test multiple microelectronic assemblies substantially simultaneously. In another example, the operations may be performed in a different order to reflect the structure of a particular microelectronic assembly in which one or more substrates or other components as described herein may be included.

Furthermore, the operations illustrated in FIGS. 7A-7E may be combined or may include more details than described. For example, the operations may be modified suitably without departing from the scope of the disclosure for IC dies that do not have a semiconductor substrate, but rather, are fabricated on other materials, such as glass or ceramic materials. Still further, the various operations shown and described may further include other manufacturing operations related to fabrication of other components of the microelectronic assemblies described herein, or any devices that may include the microelectronic assemblies as described herein. For example, the operations not shown in the figure may include various cleaning operations, additional surface planarization operations, operations for surface roughening, operations to include barrier and/or adhesion layers as desired, and/or operations for incorporating microelectronic assemblies as described herein in, or with, an IC component, a computing device, or any desired structure or device.

Example Devices and Components

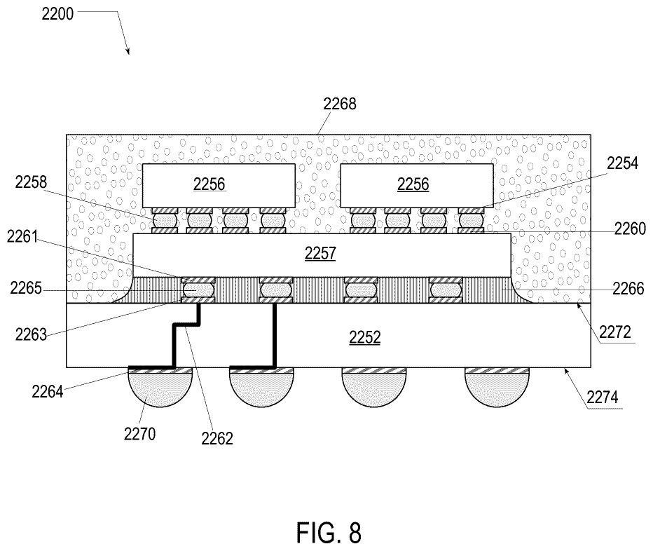

The packages disclosed herein, e.g., any of the embodiments shown in FIGS. 1-7 or any further embodiments described herein, may be included in any suitable electronic component. FIGS. 8-10 illustrate various examples of packages, assemblies, and devices that may be used with or include any of the IC packages as disclosed herein.

FIG. 8 is a side, cross-sectional view of an example IC package 2200 that may include IC packages in accordance with any of the embodiments disclosed herein. In some embodiments, the IC package 2200 may be a SIP.

As shown in the figure, package substrate 2252 may be formed of an insulator (e.g., a ceramic, a buildup film, an epoxy film having filler particles therein, etc.), and may have conductive pathways extending through the insulator between first face 2272 and second face 2274, or between different locations on first face 2272, and/or between different locations on second face 2274. These conductive pathways may take the form of any of the interconnect structures comprising lines and/or vias.

Package substrate 2252 may include conductive contacts 2263 that are coupled to conductive pathway 2262 through package substrate 2252, allowing circuitry within dies 2256 and/or interposer 2257 to electrically couple to various ones of conductive contacts 2264 (or to other devices included in package substrate 2252, not shown).

IC package 2200 may include interposer 2257 coupled to package substrate 2252 via conductive contacts 2261 of interposer 2257, first-level interconnects 2265, and conductive contacts 2263 of package substrate 2252. First-level interconnects 2265 illustrated in the figure are solder bumps, but any suitable first-level interconnects 2265 may be used, such as solder bumps, solder posts, or bond wires.

IC package 2200 may include one or more dies 2256 coupled to interposer 2257 via conductive contacts 2254 of dies 2256, first-level interconnects 2258, and conductive contacts 2260 of interposer 2257. Conductive contacts 2260 may be coupled to conductive pathways (not shown) through interposer 2257, allowing circuitry within dies 2256 to electrically couple to various ones of conductive contacts 2261 (or to other devices included in interposer 2257, not shown). First-level interconnects 2258 illustrated in the figure are solder bumps, but any suitable first-level interconnects 2258 may be used, such as solder bumps, solder posts, or bond wires. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

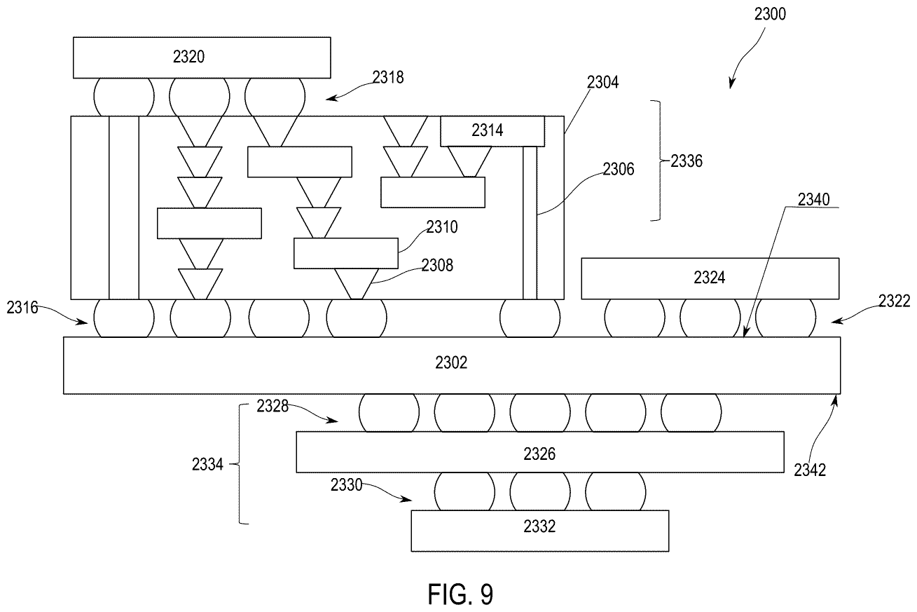

In some embodiments, underfill material 2266 may be disposed between package substrate 2252 and interposer 2257 around first-level interconnects 2265, and mold 2268 may be disposed around dies 2256 and interposer 2257 and in contact with package substrate 2252. In some embodiments, underfill material 2266 may be the same as mold 2268. Example materials that may be used for underfill material 2266 and mold 2268 are epoxies as suitable. Second-level interconnects 2270 may be coupled to conductive contacts 2264. Second-level interconnects 2270 illustrated in the figure are solder balls (e.g., for a ball grid array (BGA) arrangement), but any suitable second-level interconnects 2270 may be used (e.g., pins in a pin grid array arrangement or lands in a land grid array arrangement). Second-level interconnects 2270 may be used to couple IC package 2200 to another component, such as a circuit board (e.g., a motherboard), an interposer, or another IC package, as known in the art and as discussed below with reference to FIG. 9.

In various embodiments, any of dies 2256 may be microelectronic assembly 100 as described herein. In embodiments in which IC package 2200 includes multiple dies 2256, IC package 2200 may be referred to as a multi-chip package (MCP). Dies 2256 may include circuitry to perform any desired functionality. For example, besides one or more of dies 2256 being microelectronic assembly 100 as described herein, one or more of dies 2256 may be logic dies (e.g., silicon-based dies), one or more of dies 2256 may be memory dies (e.g., HBM), etc. In some embodiments, any of dies 2256 may be implemented as discussed with reference to any of the previous figures. In some embodiments, at least some of dies 2256 may not include implementations as described herein.

Although IC package 2200 illustrated in the figure is a flip-chip package, other package architectures may be used. For example, IC package 2200 may be a BGA package, such as an embedded wafer-level ball grid array (eWLB) package. In another example, IC package 2200 may be a wafer-level chip scale package (WLCSP) or a panel fan-out (FO) package. Although two dies 2256 are illustrated in IC package 2200, IC package 2200 may include any desired number of dies 2256. IC package 2200 may include additional passive components, such as surface-mount resistors, capacitors, and inductors disposed over first face 2272 or second face 2274 of package substrate 2252, or on either face of interposer 2257. More generally, IC package 2200 may include any other active or passive components known in the art.

In some embodiments, no interposer 2257 may be included in IC package 2200; instead, dies 2256 may be coupled directly to conductive contacts 2263 at first face 2272 by first-level interconnects 2265.

FIG. 9 is a cross-sectional side view of an IC device assembly 2300 that may include components having one or more microelectronic assembly 100 in accordance with any of the embodiments disclosed herein. IC device assembly 2300 includes a number of components disposed over a circuit board 2302 (which may be, e.g., a motherboard). IC device assembly 2300 includes components disposed over a first face 2340 of circuit board 2302 and an opposing second face 2342 of circuit board 2302; generally, components may be disposed over one or both faces 2340 and 2342. In particular, any suitable ones of the components of IC device assembly 2300 may include any of the one or more microelectronic assembly 100 in accordance with any of the embodiments disclosed herein; e.g., any of the IC packages discussed below with reference to IC device assembly 2300 may take the form of any of the embodiments of IC package 2200 discussed above with reference to FIG. 8.

In some embodiments, circuit board 2302 may be a PCB including multiple metal layers separated from one another by layers of insulator and interconnected by electrically conductive vias. Any one or more of the metal layers may be formed in a desired circuit pattern to route electrical signals (optionally in conjunction with other metal layers) between the components coupled to circuit board 2302. In other embodiments, circuit board 2302 may be a non-PCB package substrate.

As illustrated in the figure, in some embodiments, IC device assembly 2300 may include a package-on-interposer structure 2336 coupled to first face 2340 of circuit board 2302 by coupling components 2316. Coupling components 2316 may electrically and mechanically couple package-on-interposer structure 2336 to circuit board 2302, and may include solder balls (as shown), male and female portions of a socket, an adhesive, an underfill material, and/or any other suitable electrical and/or mechanical coupling structure.

Package-on-interposer structure 2336 may include IC package 2320 coupled to interposer 2304 by coupling components 2318. Coupling components 2318 may take any suitable form depending on desired functionalities, such as the forms discussed above with reference to coupling components 2316. In some embodiments, IC package 2320 may be or include IC package 2200, e.g., as described above with reference to FIG. 5. In some embodiments, IC package 2320 may include at least one microelectronic assembly 100 as described herein. Microelectronic assembly 100 is not specifically shown in the figure in order to not clutter the drawing.

Although a single IC package 2320 is shown in the figure, multiple IC packages may be coupled to interposer 2304; indeed, additional interposers may be coupled to interposer 2304. Interposer 2304 may provide an intervening package substrate used to bridge circuit board 2302 and IC package 2320. Generally, interposer 2304 may redistribute a connection to a wider pitch or reroute a connection to a different connection. For example, interposer 2304 may couple IC package 2320 to a BGA of coupling components 2316 for coupling to circuit board 2302.

In the embodiment illustrated in the figure, IC package 2320 and circuit board 2302 are attached to opposing sides of interposer 2304. In other embodiments, IC package 2320 and circuit board 2302 may be attached to a same side of interposer 2304. In some embodiments, three or more components may be interconnected by way of interposer 2304.

Interposer 2304 may be formed of an epoxy resin, a fiberglass-reinforced epoxy resin, a ceramic material, or a polymer material such as polyimide. In some implementations, interposer 2304 may be formed of alternate rigid or flexible materials that may include the same materials described above for use in a semiconductor substrate, such as silicon, germanium, and other group III-V and group IV materials. Interposer 2304 may include metal interconnects 2308 and vias 2310, including but not limited to TSVs 2306. Interposer 2304 may further include embedded devices 2314, including both passive and active devices. Such devices may include, but are not limited to, capacitors, decoupling capacitors, resistors, inductors, fuses, diodes, transformers, sensors, ESD devices, and memory devices. More complex devices such as radio frequency (RF) devices, power amplifiers, power management devices, antennas, arrays, sensors, and microelectromechanical systems (MEMS) devices may also be formed on interposer 2304. Package-on-interposer structure 2336 may take the form of any of the package-on-interposer structures known in the art.

In some embodiments, IC device assembly 2300 may include an IC package 2324 coupled to first face 2340 of circuit board 2302 by coupling components 2322. Coupling components 2322 may take the form of any of the embodiments discussed above with reference to coupling components 2316, and IC package 2324 may take the form of any of the embodiments discussed above with reference to IC package 2320.

In some embodiments, IC device assembly 2300 may include a package-on-package structure 2334 coupled to second face 2342 of circuit board 2302 by coupling components 2328. Package-on-package structure 2334 may include an IC package 2326 and an IC package 2332 coupled together by coupling components 2330 such that IC package 2326 is disposed between circuit board 2302 and IC package 2332. Coupling components 2328 and 2330 may take the form of any of the embodiments of coupling components 2316 discussed above, and IC packages 2326 and/or 2332 may take the form of any of the embodiments of IC package 2320 discussed above. Package-on-package structure 2334 may be configured in accordance with any of the package-on-package structures known in the art.

FIG. 10 is a block diagram of an example computing device 2400 that may include one or more components having one or more IC packages in accordance with any of the embodiments disclosed herein. For example, any suitable ones of the components of computing device 2400 may include a microelectronic assembly (e.g., 100) in accordance with any of the embodiments disclosed herein. In another example, any one or more of the components of computing device 2400 may include any embodiments of IC package 2200 (e.g., as shown in FIG. 5). In yet another example, any one or more of the components of computing device 2400 may include an IC device assembly 2300 (e.g., as shown in FIG. 9).

A number of components are illustrated in the figure as included in computing device 2400, but any one or more of these components may be omitted or duplicated, as suitable for the application. In some embodiments, some or all of the components included in computing device 2400 may be attached to one or more motherboards. In some embodiments, some or all of these components are fabricated onto a single SOC die.

Additionally, in various embodiments, computing device 2400 may not include one or more of the components illustrated in the figure, but computing device 2400 may include interface circuitry for coupling to the one or more components. For example, computing device 2400 may not include a display device 2406, but may include display device interface circuitry (e.g., a connector and driver circuitry) to which display device 2406 may be coupled. In another set of examples, computing device 2400 may not include an audio input device 2418 or an audio output device 2408, but may include audio input or output device interface circuitry (e.g., connectors and supporting circuitry) to which audio input device 2418 or audio output device 2408 may be coupled.

Computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. Processing device 2402 may include one or more DSPs, ASICs, CPUs, GPUs, cryptoprocessors (specialized processors that execute cryptographic algorithms within hardware), server processors, or any other suitable processing devices. Computing device 2400 may include a memory 2404, which may itself include one or more memory devices such as volatile memory (e.g., dynamic random access memory (DRAM)), nonvolatile memory (e.g., read-only memory (ROM)), flash memory, solid-state memory, and/or a hard drive. In some embodiments, memory 2404 may include memory that shares a die with processing device 2402. This memory may be used as cache memory and may include embedded dynamic random access memory (eDRAM) or spin transfer torque magnetic random access memory (STT-M RAM).

In some embodiments, computing device 2400 may include a communication chip 2412 (e.g., one or more communication chips). For example, communication chip 2412 may be configured for managing wireless communications for the transfer of data to and from computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 2412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), LTE project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 2412 may operate in accordance with other wireless protocols in other embodiments. Computing device 2400 may include an antenna 2422 to facilitate wireless communications and/or to receive other wireless communications (such as AM or FM radio transmissions).

In some embodiments, communication chip 2412 may manage wired communications, such as electrical, optical, or any other suitable communication protocols (e.g., the Ethernet). As noted above, communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

Computing device 2400 may include battery/power circuitry 2414. Battery/power circuitry 2414 may include one or more energy storage devices (e.g., batteries or capacitors) and/or circuitry for coupling components of computing device 2400 to an energy source separate from computing device 2400 (e.g., AC line power).

Computing device 2400 may include a display device 2406 (or corresponding interface circuitry, as discussed above). Display device 2406 may include any visual indicators, such as a heads-up display, a computer monitor, a projector, a touchscreen display, a liquid crystal display (LCD), a light-emitting diode display, or a flat panel display, for example.

Computing device 2400 may include audio output device 2408 (or corresponding interface circuitry, as discussed above). Audio output device 2408 may include any device that generates an audible indicator, such as speakers, headsets, or earbuds, for example.

Computing device 2400 may include audio input device 2418 (or corresponding interface circuitry, as discussed above). Audio input device 2418 may include any device that generates a signal representative of a sound, such as microphones, microphone arrays, or digital instruments (e.g., instruments having a musical instrument digital interface (MIDI) output).

Computing device 2400 may include a GPS device 2416 (or corresponding interface circuitry, as discussed above). GPS device 2416 may be in communication with a satellite-based system and may receive a location of computing device 2400, as known in the art.

Computing device 2400 may include other output device 2410 (or corresponding interface circuitry, as discussed above). Examples of other output device 2410 may include an audio codec, a video codec, a printer, a wired or wireless transmitter for providing information to other devices, or an additional storage device.

Computing device 2400 may include other input device 2420 (or corresponding interface circuitry, as discussed above). Examples of other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, computing device 2400 may be any other electronic device that processes data.

### Select Examples

Example 1 provides a microelectronic assembly (e.g., 100, FIG. 1), comprising: an interposer (e.g., 102) comprising a first portion (e.g., 104) in contact along an interface (e.g., 106) with a second portion (e.g., 108); a first IC die (e.g., 110) embedded in a dielectric material (e.g., 112) in the first portion of the interposer; and a second IC die (e.g., 116) coupled to the first portion of the interposer opposite to the second portion, in which: the second portion comprises a glass substrate (e.g., 118) with a channel (e.g., 120) within the glass substrate, a portion of the channel has an opening (e.g., 122) at the interface, a conductive pad (e.g., 124) in the first portion is exposed in the opening, and the conductive pad is coupled to a circuit (e.g., 126) in at least one of the first IC die or the second IC die.

Example 2 provides the microelectronic assembly of example 1, in which the circuit is configured to detect presence of a substance in the channel.

Example 3 provides the microelectronic assembly of example 2, in which: the conductive pad comprises a portion of a sensor, and the substance is a gas.

Example 4 provides the microelectronic assembly of example 3, in which (e.g., FIG. 5): the conductive pad is a central pad of gold, the sensor further comprises a first conductive trace (e.g., 502) on one side of the conductive pad and a second conductive trace (e.g., 504) on an opposing side of the conductive pad, the first conductive trace is conductively coupled to a drain voltage, the second conductive trace is conductively coupled to a source voltage, and the central pad of gold is conductively coupled to a gate voltage.

Example 5 provides the microelectronic assembly of any one of examples 3-4, in which the gas is hydrogen.

Example 6 provides the microelectronic assembly of any one of examples 3-5, in which the microelectronic assembly is part of a control system in an automobile.

Example 7 provides the microelectronic assembly of example 2, in which (e.g., FIGS. 4A-4C): the conductive pad has a coating (e.g., 402) on a surface exposed in the opening, and the substance comprises biological molecules (e.g., 406).

Example 8 provides the microelectronic assembly of example 7, in which: ligands (e.g., 404) are attached to the coating on the conductive pad, and the ligands are configured to bind to the biological molecules.

Example 9 provides the microelectronic assembly of any one of examples 7-8, in which: the biological molecules are in an analyte solution, and the analyte solution is pumped through the channel.

Example 10 provides the microelectronic assembly of example 1, in which the circuit is a thermal circuit, and the channel is configured to carry heat away from the conductive pad.

Example 11 provides the microelectronic assembly of example 10, in which the conductive pad comprises copper.

Example 12 provides the microelectronic assembly of any one of examples 1-11, in which the channel has angled baffles (e.g., 202).

Example 13 provides the microelectronic assembly of any one of examples 1-13, in which: the channel has an entry opening (e.g., 128) and an exit opening (e.g., 129), and a fluid enters the channel at the entry opening, contacts the conductive pad, and exits the channel at the exit opening.

Example 14 provides the microelectronic assembly of example 13, in which the entry opening and the exit opening are on a common surface (e.g., 130) of the interposer.

Example 15 provides the microelectronic assembly of example 13, in which the entry opening and the exit opening are on opposite surfaces (e.g., 130, 132) of the interposer.

Example 16 provides the microelectronic assembly of any one of examples 13-15, in which the fluid is at least one of: a gas, a coolant, and an analyte solution.

Example 17 provides the microelectronic assembly of any one of examples 1-16, in which: the glass substrate further comprises a plurality of channels, each channel has an opening at the interface, and respective conductive pads in the first portion are exposed at the corresponding openings.

Example 18 provides the microelectronic assembly of any one of examples 1-18, in which: the glass substrate includes conductive TGVs (e.g., 142), and the TGVs are around the channel.

Example 19 provides the microelectronic assembly of example 18, in which: the first portion further includes TDVs (e.g., 144) in the dielectric material, and at least some of the TDVs are conductively coupled to at least some of the TGVs.

Example 20 provides the microelectronic assembly of any one of examples 1-19, further comprising a third IC die coupled to the first portion of the interposer opposite to the second portion, in which the first IC die conductively couples the second IC die and the third IC die.

Example 21 provides a package substrate, comprising: a first layer of organic dielectric material, the first layer having a first side and an opposing second side; and a second layer of glass attached to the first side of the first layer, in which: the second layer of glass comprises channels configured for flow of a fluid therethrough, and the first layer comprises bond-pads on the second side configured to be attached to IC dies.

Example 22 provides the package substrate of example 21, in which a linear dimension of a cross-section of any one of the channels is in a range between approximately 100 nanometers and 500 micrometers.

Example 23 provides the package substrate of example 22, in which the linear dimension of the cross-section of any one of the channels is approximately 10 micrometers.

Example 24 provides the package substrate of any one of examples 21-23, in which the fluid is at least one of: a gas, a liquid coolant, and an analyte solution comprising biological molecules.

Example 25 provides the package substrate of any one of examples 21-24, in which: a first portion of the channels is separated from the first side of the first layer by the glass, a second portion of the channels is in contact with the first side, the channels have respective openings where the second portion contacts the first side, corresponding conductive pads in the first layer are exposed through the openings.

Example 26 provides the package substrate of example 25, in which: a third portion of the channels couples the first portion and the second portion, the third portion comprises slanted baffle structures in the channels.

Example 27 provides the package substrate of any of examples 25-26, in which a surface of the conductive pad exposed through the opening is coated with a metal inert to the fluid.

Example 28 provides the package substrate of any one of examples 25-27, in which: the conductive pad is coupled to a thermal circuit, and the thermal circuit is configured to transfer heat away from the IC dies.

Example 29 provides the package substrate of example 25, in which: the conductive pad is coupled to a detection circuit, a surface of the conductive exposed at the opening is coated with a layer of ligands, and the detection circuit is configured to detect presence of a biological molecule that binds with the ligands.

Example 30 provides the package substrate of example 25, in which: the conductive pad is coupled to a detection circuit, the detection circuit comprises a first conductive trace and a second conductive trace in the first layer conductively coupled to the conductive pad, the first conductive trace is configured to be at a first voltage, the second conductive trace is configured to be at a second voltage different from the first voltage, the conductive pad is configured to be at a third voltage different from the first voltage and the second voltage, contact between the conductive pad and a gas in the channel is configured to cause a change in a flow of current through the conductive pad.

Example 31 provides an interposer, comprising: a first layer of organic dielectric material, the first layer having a first side and an opposing second side; and a second layer of glass attached to the first side of the first layer, in which: the second layer of glass comprises microfluidic channels having a linear cross-sectional dimension in a range between approximately 100 nanometers and 500 micrometers, the first layer comprises bond-pads on the second side configured to be attached to IC dies, and the first layer comprises a bridge IC die in the organic dielectric material and TDVs around the bridge IC die, the bridge IC die conductively coupling a subset of the bond-pads on the second side.

Example 32 provides the interposer of example 31, in which: the second layer comprises TGVs in the glass, and a subset of the TDVs in the first layer is conductively coupled to another subset of the TGVs in the second layer.

Example 33 provides the interposer of example 32, in which: the bond-pads on the second side of the first layer are first bond-pads, the second layer comprises second bond-pads opposite to the first layer, the second bond-pads are configured to be coupled to at least one of a package substrate or a motherboard, and the TGVs are conductively coupled to the second bond-pads.

Example 34 provides the interposer of any one of examples 32-33, in which the microfluidic channels wind around the TGVs.

Example 35 provides the interposer of any one of examples 31-34, in which the microfluidic channels have openings on sides of the interposer orthogonal to the first side or the second side.

Example 36 provides the interposer of example 35, in which the openings are on two opposite sides of the interposer.

Example 37 provides the interposer of example 35, in which the openings are on a same side of the interposer.

Example 38 provides the interposer of any one of examples 31-37, in which: the microfluidic channels comprise openings at an interface with the first side, and conductive pads coupled to detection circuits are exposed through the openings.

Example 39 provides the interposer of example 38, in which the detection circuits are in one or more IC dies coupled to the bond-pads on the second side of the first layer.

Example 40 provides the interposer of example 38, in which the detection circuits are in the bridge IC die.

Example 41 provides a method, comprising: providing a support structure of glass; plating conductive pads on a first side of the support structure; forming TGVs through the glass, the TGVs extending between the first side and an opposite second side of the support structure; etching channels in the glass, the channels being around the TGVs and having openings contiguous with a subset of the conductive pads; depositing organic dielectric material on the first side of the support structure; forming conductive traces, bond-pads, and vias in the organic dielectric material, the bond-pads being on a side of the organic dielectric material opposite to the support structure; and coupling IC dies to the bond-pads.

Example 42 provides the method of example 41, in which etching the channels comprises using a sodium hydroxide etchant.

Example 43 provides the method of any one of examples 41-42, in which the subset of the conductive pads comprise gold.

Example 44 provides the method of any one of examples 41-43, further comprising forming additional bond-pads on the second side of the support structure, the TGVs conductively coupled to the additional bond-pads.

Example 45 provides the method of any one of examples 41-44, further comprising: conductively coupling the subset of the conductive pads to a detection circuit, pumping a fluid through the channels, detecting, by the detection circuit, presence of at least one of a gas or biological molecules in the fluid.

Example 46 provides the method of example 45, further comprising: before pumping the fluid, pumping a ligand solution through the channels such that the ligands bind to an exposed surface of the subset of the conductive pads, in which the ligands are configured to attach to the biological molecules.

Example 47 provides the method of any one of examples 45-46, in which the detection circuit comprises a metal-oxide semiconductor field effect transistor (MOSFET) sensor configured to detect hydrogen in the fluid.

Example 48 provides the method of any one of examples 45-47, in which the detection circuit is in the IC dies.

Example 49 provides the method of any one of examples 41-48, further comprising: conductively coupling the subset of the conductive pads to a thermal circuit, pumping a liquid coolant through the channels, operating the IC dies such that heat is produced by the IC dies, transferring the heat through the thermal circuit to the conductive pads, and transferring the heat from the conductive pads to the liquid coolant.

Example 50 provides the method of any one of examples 41-49, further comprising embedding a bridge IC die in the organic dielectric material, in which the bridge IC die comprises conductive pathways between the IC dies.

The above description of illustrated implementations of the disclosure, including what is described in the abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

1. A microelectronic assembly, comprising:
an interposer comprising a first portion in contact along an interface with a second portion;
a first integrated circuit (IC) die embedded in a dielectric material in the first portion of the interposer; and
a second IC die coupled to the first portion of the interposer opposite to the second portion,
wherein:
the second portion comprises a glass substrate with a channel within the glass substrate,
a portion of the channel has an opening at the interface,
a conductive pad in the first portion is exposed in the opening, and
the conductive pad is coupled to a circuit in at least one of the first IC die or the second IC die.

2. The microelectronic assembly of claim 1, wherein the circuit is configured to detect presence of a substance in the channel.

3. The microelectronic assembly of claim 2, wherein:
the conductive pad comprises a portion of a sensor, and
the substance is a gas.

4. The microelectronic assembly of claim 3, wherein:
the conductive pad is a central pad of gold,
the sensor further comprises a first conductive trace on one side of the conductive pad and a second conductive trace on an opposing side of the conductive pad,
the first conductive trace is conductively coupled to a drain voltage,
the second conductive trace is conductively coupled to a source voltage, and
the central pad of gold is conductively coupled to a gate voltage.

5. The microelectronic assembly of claim 2, wherein:
the conductive pad has a coating on a surface exposed in the opening, and
the substance comprises biological molecules.

6. The microelectronic assembly of claim 5, wherein:
ligands are attached to the coating on the conductive pad, and
the ligands are configured to bind to the biological molecules.

7. The microelectronic assembly of claim 1, wherein the circuit is a thermal circuit, and the channel is configured to carry heat away from the conductive pad.

8. The microelectronic assembly of claim 1, wherein:
the channel has an entry opening and an exit opening, and
a fluid enters the channel at the entry opening, contacts the conductive pad, and exits the channel at the exit opening.

9. The microelectronic assembly of claim 1, wherein:
the glass substrate includes conductive through-glass vias (TGVs), and
the TGVs are around the channel.

10. A package substrate, comprising:
a first layer of organic dielectric material, the first layer having a first side and an opposing second side; and
a second layer of glass attached to the first side of the first layer,
wherein:
the second layer of glass comprises one or more channels configured for flow of a fluid therethrough, and
the first layer comprises bond-pads on the second side configured to be attached to IC dies.

11. The package substrate of claim 10, wherein a linear dimension of a cross-section of any one of the channels is in a range between approximately 100 nanometers and 500 micrometers.

12. The package substrate of claim 10, wherein:
a first portion of the one or more channels is separated from the first side of the first layer by the glass,
a second portion of the one or more channels is in contact with the first side,
the one or more channels have respective openings where the second portion contacts the first side,
corresponding conductive pad in the first layer are exposed through the openings.

13. The package substrate of claim 12, wherein:
a third portion of the one or more channels couples the first portion and the second portion,
the third portion comprises slanted baffle structures in the one or more channels.

14. The package substrate of claim 12, wherein:
the conductive pad is coupled to a detection circuit,
a surface of the conductive exposed at the opening is coated with a layer of ligands, and
the detection circuit is configured to detect presence of a biological molecule that binds with the ligands.

15. The package substrate of claim 12, wherein:
the conductive pad is coupled to a detection circuit,
the detection circuit comprises a first conductive trace and a second conductive trace in the first layer conductively coupled to the conductive pad,
the first conductive trace is configured to be at a first voltage,
the second conductive trace is configured to be at a second voltage different from the first voltage,
the conductive pad is configured to be at a third voltage different from the first voltage and the second voltage,
contact between the conductive pad and a gas in the channel is configured to cause a change in a flow of current through the conductive pad.

16. An interposer, comprising:
a first layer of organic dielectric material, the first layer having a first side and an opposing second side; and
a second layer of glass attached to the first side of the first layer,
wherein:
the second layer of glass comprises microfluidic channels having a linear cross-sectional dimension in a range between approximately 100 nanometers and 500 micrometers,
the first layer comprises bond-pads on the second side configured to be attached to integrated circuit (IC) dies, and
the first layer comprises a bridge IC die in the organic dielectric material and through-dielectric vias (TDVs) around the bridge IC die, the bridge IC die conductively coupling a subset of the bond-pads on the second side.

17. The interposer of claim 16, wherein:
the second layer comprises TGVs in the glass, and
a subset of the TDVs in the first layer is conductively coupled to another subset of the TGVs in the second layer.

18. The interposer of claim 17, wherein:
the bond-pads on the second side of the first layer are first bond-pads,
the second layer comprises second bond-pads opposite to the first layer,
the second bond-pads are configured to be coupled to at least one of a package substrate or a motherboard, and
the TGVs are conductively coupled to the second bond-pads.

19. The interposer of claim 16, wherein:
the microfluidic channels comprise openings at an interface with the first side, and
conductive pads coupled to detection circuits are exposed through the openings.

20. The interposer of claim 19, wherein the detection circuits are in one or more IC dies coupled to the bond-pads on the second side of the first layer.
